(19) United States
(12) Patent Application Publication
(10) Pub. No.: US 2006/0131568 A1
(43) Pub. Date: Jun. 22, 2006

(54) Device having an organic transistor integrated with an organic light-emitting diode's heterojunctions

(76) Inventors: Hsin-Fei Meng, Hsinchu (TW); Sheng-Fu Horng, Hsinchu (TW); Chien-Shu Hsu, Hsinchu (TW); Wen-Tsang Liu, Taipei City (TW); Yu-Zhong Yang, Dali City (TW)

Correspondence Address: BUCKNAM AND ARCHER, 1077 NORTHERN BOULEVARD, ROSLYN, NY, 11576, US

(21) Appl. No.: 11/120,233

(22) Filed: May 2, 2005

(30) Foreign Application Priority Data
Dec. 20, 2004 (TW) 093139632

(51) Int. Cl. H01L 29/08

(52) U.S. Cl. 257/40

(57) ABSTRACT

A device having an organic transistor device integrated with an organic light-emitting diode's heterojunctions. This device at least comprises: a transparent substrate, an organic transistor and an organic light-emitting diode. The organic transistor at least includes an organic semiconductor layer, one of the organic semiconductor layers serves as the organic active layer of the organic light-emitting diode, and the organic active layer and the other organic semiconductor layers form heterojunctions. The present invention uses the organic semiconductor layer to simultaneously form the organic active layer of the organic transistor, so that the organic light-emitting diode and the organic transistor can be easily integrated together so as to solve the problem of the poor luminance efficiency of a conventional integrated organic transistor and organic light-emitting diode and the problem of its high manufacturing cost.

### BACKGROUND OF THE INVENITON

1. Field of the Invention

The present invention relates to an organic light-emitting diode (OLED) and an organic transistor, and particularly to an organic transistor integrated with an organic light-emitting diode's heterojunctions.

2. Description of the Related Art

Since organic light-emitting diodes have a lot of advantages, such as low operation voltage, high brightness, light/thin in size, wide viewing angle, high contrast, etc., they are gradually and widely used in a flat panel display. Amorphous Si thin film transistors (a-Si TFTs), poly-Si thin film transistors (poly-Si TFTs) and organic thin film transistors (OTFTs) can be used to drive the organic light-emitting diodes. To simply manufacture process and reduce manufacture cost, the OTFTs are the best choice to drive the OLEDs. Therefore, at present, many groups have introduced OTFT and OLED integrating techniques for manufacturing devices used in an organic active matrix display.

For the currently-developing organic active matrix pixels, organic light-emitting diodes and drive transistors are separately manufactured, and the semiconductor material of the transistors and the organic layer material of the organic light-emitting diodes are different, resulting in high complexity and cost in manufacture. If the organic light-emitting diodes and the organic thin film transistors are manufactured at the same time, the complexity and cost in manufacture can be highly reduced.

The prior U.S. Pat. No. 6,150,668 has disclosed a technique in which OTFTs and OLEDs can be manufactured at the same time. For example, an organic semiconductor material is selected to be used for both the semiconductor layers of the OTFTs and the hole transport layers of the OLEDs at the same time. However, this patent did not mention whether or not the OLEDs which are formed with the organic semiconductor material serving as the hole transport layers thereof have their luminous efficiency reduced or are different from polymer light-emitting diodes (PLEDs) which are formed with PEDOT serving as the hole transport layers thereof.

The prior U.S. Pat. No. 6,037,718 to Ngami suggested a stacked organic npn-type transistor and OLED integrated device. The organic npn-type transistor is stacked on the OLED, and supplies a large current to drive the OLED. In this structure, an n-type organic semiconductor material can serve as both the collector of the npn transistor and the electron transport layer of the OLED. Moreover, a p-type organic semiconductor material can serve as both the collector of the pnp transistor and the hole transport layer of the OLED. However, it is required to stack more layers of organic material and electrodes in the manufacture process, making the process complicated, and it did not mention whether or not the luminous efficiency of the OLED is affected. Furthermore, currently, there are no appropriate n-type organic semiconductor materials with high conductivity.

In “Integrated Optoelectronic Devices Based on Conjugated Polymers” Science 280, 1741 (1998), submitted by Henning Sirringhaus, Nir Tessler, and Richard H. Friend, a device structure formed on a silicon substrate uses a P3HT polymer serving as the semiconductor layer material of thin film transistors to drive organic light-emitting diodes which have an MEH-PPV polymer serving as a light-emitting layer material, and the organic light-emitting diodes emit lights upwards through the cathodes thereof. Therefore, the luminous efficiency of the organic light-emitting diodes is reduced due to the light absorption on the cathodes. Furthermore, the manufacture steps are quite complicated.

In “Organic Smart Pixels” Appl. Phys. Lett., 73, 142, submitted by A. Dodabalapur, Z. Bao, A. Makhija, J. G. Laquindanum, V. R. Raju, Y. Feng, H. E. Katz, and J. Rogers, a device structure formed on a glass substrate uses a P3HT polymer serving as the semiconductor layer material of thin film transistors to drive organic light-emitting diodes which have an Alq small molecule serving as a light-emitting layer material. The result of electrical measurement for the transistors shows no current saturation phenomena. The luminous efficiency of the organic light-emitting diodes is low, and the organic material of the organic light-emitting diodes is a small molecular material and must be evaporated in a high-vacuum chamber, resulting in high manufacture cost. Moreover, P3HT cannot be present in the LED structure.

In “Organic Smart Pixels and Complementary Inverter Circuits Formed on Plastic Substrates by Casting and Rubber Stamping” IEEE Electronic Devices Lett., 21, 100 (2000), submitted by J. A. Rogers, Z. Bao, A. Dodabalapur, and A. Makhija, transistors are formed by a stamp printing method, and organic light-emitting diodes are driven on the same substrate. The manufacture steps are simple, but the resolution of the stamp printing is low. Therefore, the device has a large size. Since the hole transport layer of an organic light-emitting diodes is PEDOT, the distance between a coating region and a transistor active layer must be considered when spin coating is performed to form the hole transport layer, so as not to affecting the property of the transistor. This factor causes trouble to the formation of the hole transport layer.

In “Organic Light-Emitting Diodes Driven by Pentacene-Based Thin-Film Transistors” Appl. Phys. Lett., 83, 3410 (2003), submitted by M. Kitamura, T. Imada, and Y. Arakawa, an organic pentacene small molecule is used as the semiconductor layer material of thin film transistors in order to drive organic light-emitting diodes which use an organic Alq3 small molecule as the light-emitting layers thereof. A high-vacuum chamber is required to evaporate the small molecular material, resulting in high manufacture cost.

In “Organic Transistor Circuits for Application to Organic Light-Emitting Diode Displays” J pn. J. Appl. Phys. Vol. 42 (2003), submitted by Masatoshi KITAMURA1, Tadahiro IMADA1 and Yasuhiko ARAKAWA1, active pixels are formed of a CuPc small molecule. In its structure, two organic thin film transistors, a capacitor and an organic light-emitting diode are included. The organic thin film transistors use CuPc serving as the semiconductor material of the active layers thereof, and also the organic light-emitting diode uses a CuPc small molecule material serving as the hole transport layer thereof. Therefore, the number of the manufacture steps is reduced. However, this paper did not mention that the luminous efficiency of the organic light-emitting diode with CuPc serving as HTL is increased or reduced.

In “White Light Emission from Exciplex in a Bilayer Device with Two Blue Light-Emitting Polymers” Appl. Phys. Lett., 73, 426 (1998), submitted by Ching-Ian Chao and Show-An Chen, two blue polymer materials of poly (N-vinylcarbazole) (PVK) and poly (2-dodecyl-p-phenylene) (C120-PPP) are used to form a bilayer structure of polymer diode. If it is immiscible at the junction, a blue light is generated as a unilayer structure of C120-PPP splitting diode does. If it is miscible at the junction, an exciplex is generated. The color of light emitted from the exciplex is superposed on the color of light emitted from a host excition so as to generate a white light, and therefore, a white OLED can be manufactured. However, this OLED structure has poor efficiency and low brightness, and it is difficult for this manufacture process to integrate organic electronic devices.

For the current OLEDs, if they need to emit different colors of light, a chemosynthesis method is used to generate different organic light-emitting materials. This method costs great man power, and much more materials and time for process. And, in a conventional organic full-color display, most colors of light are formed by positioning and blending three primary colors of light (red, blue and green). However, there are still a lot of problems needed to be resolved in positioning three primary colors.

### SUMMARY OF THE INVENTION

Therefore, an object of the present invention is to provide a device having an organic transistor integrated with a heterojunction of an organic light-emitting diode. In the present invention, on an organic semiconductor material, a film of another organic material is formed, wherein a heterojunction is formed between the organic semiconductor material and the organic material. The present invention uses this heterojunction which can emit lights, to form an organic light-emitting diode, and also uses the organic semiconductor material to form an organic transistor, so as to easily integrate the organic light-emitting diode and the organic transistor. As a result, the problems of the poor luminance efficiency of the integrated organic transistor and organic light-emitting diode, manufacturing complexity and high cost in the prior art can be solved.

In order to achieve the above objects, the present invention provides a device having an organic transistor integrated with a heterojunction of an organic light-emitting diode. This device at least comprises: a transparent substrate, an organic transistor and an organic light-emitting diode, wherein the organic transistor comprises source, drain, gate and at least one organic semiconductor layer; and the organic light-emitting diode comprises anode, cathode and an organic active layer, wherein the source or drain is coupled to the anode. The organic transistor and the organic light-emitting diode are formed on the transparent substrate. One of the organic semiconductor layers serves as the organic active layer of the organic light-emitting diode, and the organic active layer and the other organic semiconductor layers form heterojunctions. Herein, the organic light-emitting diode emits lights from a heterojunction, synthesized lights generated by more than two hetetrojunction or synthesized lights generated by a heterojunction and a host excition. In a preferred embodiment of the present invention, a white light can be generated by superposing the three primary colors of light.

In summary, since the organic light-emitting diodes and the drive transistors of the developing organic active matrix pixels are formed separately, and the semiconductor layer material of the transistors and the organic layer material of the light-emitting diodes are different, resulting in high manufacturing complexity and cost. In the present invention, electronic devices and light-emitting devices are integrated on a flexible substrate, and the organic semiconductor layer of the light-emitting diode is used as the active layer of the organic transistor, so as to greatly reduce the manufacturing complexity and cost. Moreover, a light of required color can be generated with heterojunctions only by forming different organic light-emitting material films on the organic semiconductor material and selecting appropriate energy gaps (EGs). For example, a white light source is generated with a large area without positioning, and can work together with a color filter to attain the purpose of full-color display. Accordingly, organic active matrix pixels with high efficiency can be manufactured with the device of the present invention.

The above and other objects, features and advantages of the present invention will become more fully understood from the detailed descriptions of the preferred embodiment given hereinafter and the accompanying drawings.

### BRIEF DESCRIPTION OF THE DRAWINGS

FIGS. 1a and 1b are structural energy band graphs of organic heterojunction light-emitting diodes according to a preferred embodiment of the present invention;

FIGS. 1c and 1d are comparative graphs of organic light-emitting diodes which uses PEDOT serving as hole transport layers according to a preferred embodiment of the present invention;

FIG. 3a is a spectrogram of a P3Ht+PF green material used according to a preferred embodiment of the present invention.

FIG. 3b is a graph showing the relationship between luminance brightness and current density of the P3HT+PF green material according to a preferred embodiment of the present invention;

FIG. 4 is a white spectrogram according to a preferred embodiment of the present invention;

FIG. 5 shows a structure in which an organic light-emitting diode is driven by an organic thin film transistor according to a preferred embodiment of the present invention.

FIG. 6a is a characteristic graph of an organic thin film transistor according to a preferred embodiment of the present invention; and

FIG. 6b is a characteristic graph of an integrated organic light-emitting diode and organic thin film transistor according to a preferred embodiment of the present invention,

FIG. 7 is a comparative table showing the efficiency and brightness of different light-emitting materials used when P3HT and PEDOT serve as hole transport layers.

### DESCRIPTION OF THE PREFERRED EMBODIMENTS

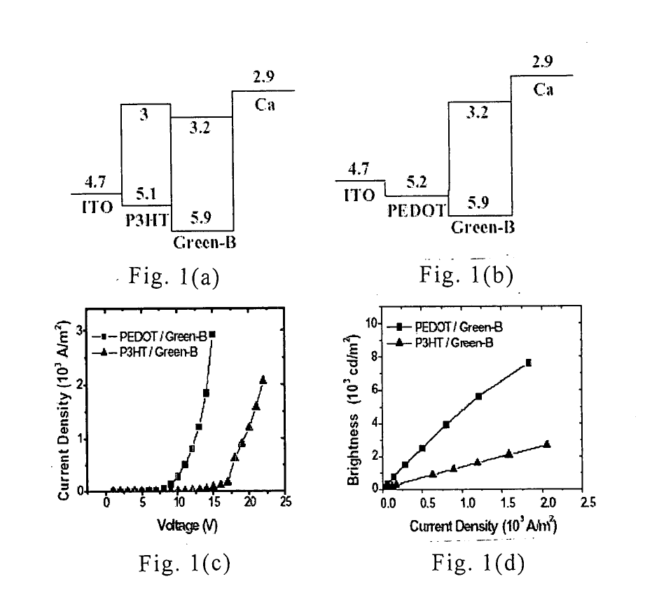

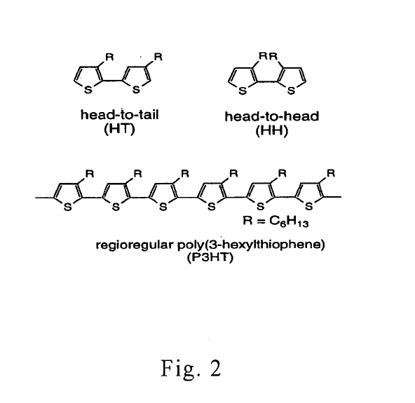

FIGS. 1a and 1b are structural energy band graphs of organic heterojunction light-emitting diodes according to a preferred embodiment of the present invention. FIGS. 1c and 1d are comparative graphs of organic light-emitting diodes which uses poly ethylenedioxythiophene (PEDOT serving as hole transport layers (HTLs) thereof according to a preferred embodiment of the present invention. Please referring to FIGS. 1a, 1b, 1c, and 1d simultaneously, in the organic light-emitting diode structure using PEDOT as a hole transport layer, the thickness of an organic light-emitting layer can be controlled. When the organic light-emitting layer is thick, the body is much superior to the heterojunction in light emission so as to make the entire color of light close to the color of light emitted from the organic light-emitting layer. When the organic light-emitting layer is thin, the heterojunction is superior to the body in light emission, and an exciplex can be used to generate required colors of light.

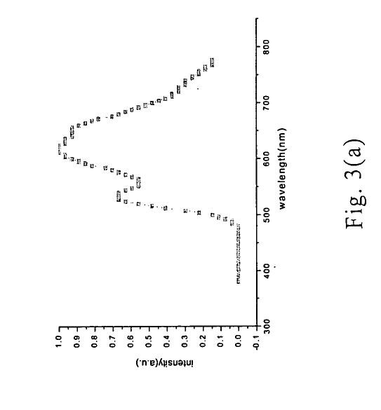

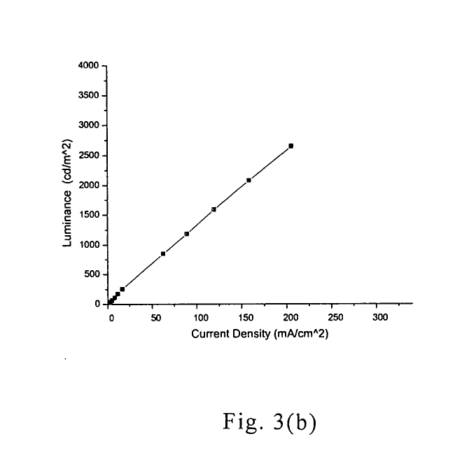

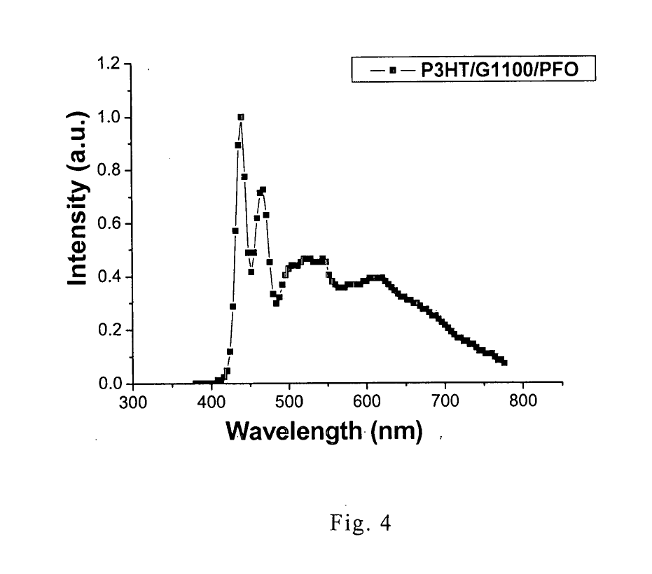

In a preferred embodiment of the present invention, FIG. 3a is a spectrogram of a P3HT+PF green light emitting material used in the present invention, and FIG. 3b is a graph showing the relationship between the luminance brightness and the current density of the P3HT+PF green light emitting material. Furthermore, referring to FIG. 4, a red light is generated by a heterojunction exciplex of P3HT and G1100, and a green light and a blue light are generated by G1100 and PFO, respectively. FIG. 2 shows a structural formula of poly-(3-hexylthiophene) (P3HT) of the present invention.

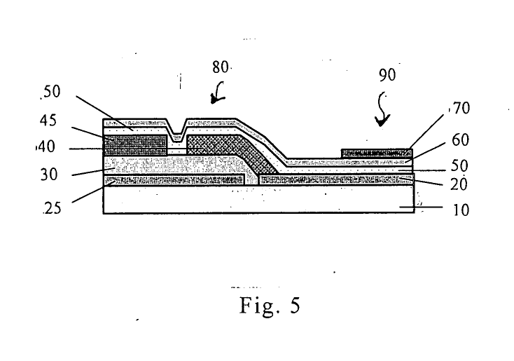

FIG. 5 shows a structure in which an organic light-emitting diode is driven by an organic thin film transistor according to a preferred embodiment of the present invention. Please referring to FIG. 5, a device having an organic thin film transistor 80 integrated with the heterojunctions of an organic light-emitting diode 90 is manufactured according to the present invention. The manufacturing method comprises the following steps of: first, etching an transparent electrode of indium tin oxide (ITO) 10 to obtain anode 20 of the light-emitting diode and transistor gate 25, which has a thickness of 150 nm; then, growing and patterning a silicon dioxide 30; next, completing the formation of transistor source 45 and drain 40 by photolithography and thermal gold evaporating as well as peeling, wherein gold is 200 nm in thickness; then, spin coating with an organic semiconductor layer material 50 (such as 0.6% P3HT in toluene, having 35 nm in thickness), and baking it in vacuum (10⁻³ torr) at a temperature of 125° C. for 100 minutes; subsequently, spin coating with a light-emitting layer material 60 (such as 2% PF green light material in toluene, having 180 nm in thickness) of the light-emitting diode 90 and baking it in vacuum (10⁻³ torr) at a temperature of 125° C. for 60 minutes; finally, evaporating cathode 70 (such as calcium (10 nm˜50 nm) covered with aluminum (50 nm˜100 nm)) at pressure of 10⁻⁶˜10⁻⁷ torr.

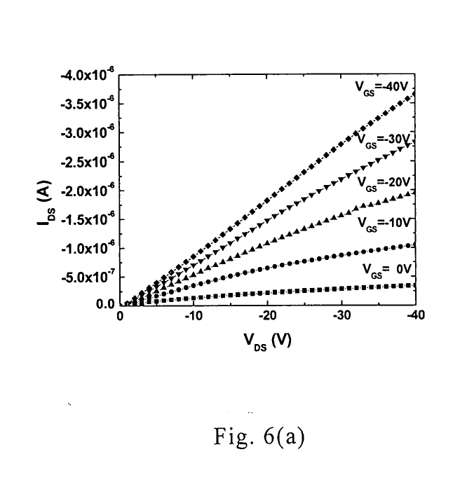

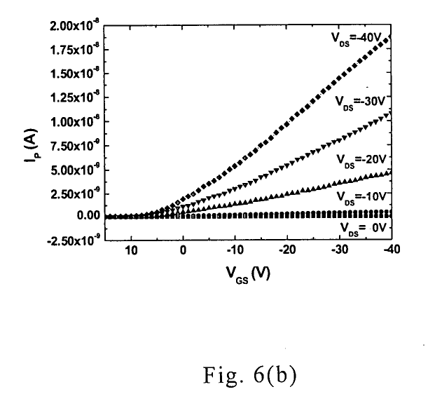

FIG. 6a is a characteristic graph of an organic thin film transistor according to a preferred embodiment of the present invention. As known from the graph, the organic thin film transistor of the present invention has a maximum supply current of 3.6A, a field effect hole carrier mobility of 0.0047 cm²/V·s, and a threshold voltage of 15.4 voltage. FIG. 6b is a characteristic graph of an integrated organic light-emitting diode and organic thin film transistor according to the present invention, wherein Ip is a light intensity detected by a light detector.

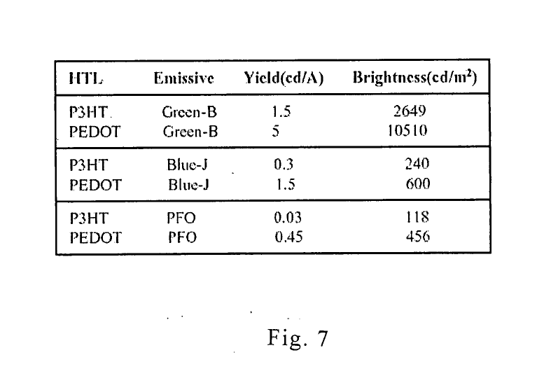

FIG. 7 is a comparative table showing the efficiency and luminance of different light-emitting materials used when P3HT and PEDOT serve as hole transport layers. As learned from this table, the efficiency of an organic light-10 emitting diode using conventional PEDOT is only about three times higher than that using P3HT.

In a preferred embodiment of the present invention, an organic active layer is at least one of the following semiconductor materials: regioregular poly (3-alkylthiophene, pentacene, oligothiophene, polythiophene, polyacetylene, polyacetylene copper phthalocyanine (CuPc), poly-9,9′ dioctyl-fluorene-co-bithiophene (F8T2), poly (2-methoxy-5)(2′-ethyl-hexyloxy)-1.4-phenylene vinylene) (MEH-PPV), phthalocyanine coordination compounds), bis-benzodithiophene, Di-R-anthradithiophene, wherein R is CₘH₂ₘ₊₁, wherein m is 0˜18 or C_{y}H_{2y+1}OC_{z}H_{2z}, wherein z+y=4˜17, y is larger than zero, and z is larger than 2, poly (2, 5 thienylenevinylene), poly (p-phenylene vinylene) (PPV) and its derivative, poly (fluorence) (PF) and its derivative, PPP and its derivative.

In an organic light-emitting diode and an organic transistor integrated with a heterojunction according to a preferred embodiment of the present invention, synthesized lights generated by a heterojunction and a host excition can be superposed to form a white light with three primary colors of light, and a white light-emitting diode which emits a white light consisting of three primary colors of light can be manufactured. Furthermore, for example, the white light-emitting diode can work with a color filter to construct an organic full-color display.

In another preferred embodiment of the present invention, the light-emitting mechanism of the heterojunction is at least one of exciplex light emission, excimer light emission, electromer light emission and exectroplex light emission.

In a preferred embodiment of the present invention, an organic semiconductor material is used to manufacture an organic transistor which is integrated with an organic light-emitting diode so as to form an organic active matrix full-color display. This organic transistor is at least one of an organic thin film transistor, an organic field effect transistor, an organic bi-polar junction transistor, an organic vertical transistor and an organic metal base-transistor.

Although the invention has been described in terms of the preferred embodiment, various changes and modifications can be made without departure from the spirit and scope of the present invention which is determined by the claims below.

### LIST OF MAJOR ELEMENTS AND THEIR CORRESPONDING REFERENCE NUMERALS

10 Substrate
20 Indium Tin Oxide (ITO)
25 Gate
30 Silicon Dioxide
40 Drain
45 Source
50 P3HT
60 Light-Emitting Layer
70 Electrode
80 Organic Thin Film Transistor
90 Organic Light-Emitting Diode

What is claimed is:

1. A device having an organic transistor integrated with an organic light-emitting diode's heterojunctions, comprising: a transparent substrate; an organic transistor comprising a source, a drain, a gate and at least one organic semiconductor layer; an organic light-emitting diode comprising an anode, a cathode and an organic active layer, wherein the organic transistor and the organic light-emitting diode are formed on the transparent substrate, characterized in that one of the organic semiconductor layers serves as the organic active layer of the organic light-emitting diode, and the organic active layer and the other organic semiconductor layers form heterojunctions.

2. The device as claimed in claim 1, wherein the organic semiconductor layer serving as the organic active layer at least comprises the following materials: regioregular poly (3-alkylthiophene, pentacene, oligothiophene, polythiophene, polyacetylene, polyacetylene copper phthalocyanine (CuPc), poly-9,9′ dioctyl-fluorene-co-bithiophene (F8T2), poly (2-methoxy-5)(2′-ethyl-hexyloxy)-1.4-phenylene vinylene) (MEH-PPV), phthalocyanine coordination compounds), bis-benzodithiophene, Di-R-anthradithiophene, wherein R is CₘH₂ₘ₊₁, wherein m is 0˜18 or C_{y}H_{2y+1}OC_{z}H_{2z}, wherein z+y=4˜17, y is larger than zero, and z is larger than 2, poly (2, 5 thienylenevinylene), poly (p-phenylene vinylene) (PPV) and its derivative, poly (fluorence) (PF) and its derivative, PPP and its derivative.

3. The device as claimed in claim 1, wherein the organic light-emitting diode emits lights from a heterojunction, synthesized lights generated by more than two heterojunctions or synthesized lights generated by a heterojunction and a host excition.

4. The device as claimed in claim 3, wherein synthesized lights generated by the heterojunction and the host excition can be superposed to form a white light with three primary colors of light.

5. The device as claimed in claim 4, wherein a white light-emitting diode emitting a white light with three primary colors is manufactured.

6. The device as claimed in claim 5, wherein the white light-emitting diode works together with a color filter to form an organic full-color display.

7. The device as claimed in claim 1, wherein the light-emitting mechanism of the heterojunction is at least one of exciplex light emission, excimer light emission, electromer light emission and electroplex light emission.

8. The device as claimed in claim 1, wherein the source or the drain is coupled to the anode.

9. The device as claimed in claim 1, wherein the gate and the anode are indium tin oxide.

10. The device as claimed in claim 2, wherein the organic semiconductor layer material is used to manufacture the organic transistor and integrated with the organic light-emitting diode so as to manufacture an organic active matrix full-color display.

11. The device as claimed in claim 10, wherein the organic transistor is at least one of an organic thin film transistor, an organic field effect transistor, an organic bi-polar junction transistor, an organic vertical transistor and an organic metal base-transistor.
